(19) United States
(12) Patent Application Publication
(10) Pub. No.: US 2026/0268038 A1
(43) Pub. Date: Sep. 10, 2026

(54) Method for Modeling a Manufacturing Process

(71) Applicant: Robert Bosch GmbH, Stuttgart (DE)

(72) Inventors: Michael Schaenzel, Heuchlingen (DE); Emil Sauter, Ulm (DE); Hermann Autenrieth, Ruit (DE)

(21) Appl. No.: 19/558,927

(22) Filed: Mar. 6, 2026

(30) Foreign Application Priority Data
Mar. 10, 2025 (DE) 10 2025 108 857.8

(51) Int. Cl. G06F 30/20

(52) U.S. Cl. CPC G06F 30/20

(57) ABSTRACT

A method for modeling a manufacturing process includes (i) defining a target variable, input variables, and constant physical variables within the manufacturing process, (ii) determining dimensionless metrics based on the defined input variables, the defined target variable, and the defined constant physical variables by way of a dimensional analysis, (iii) creating a first regression model based on the determined dimensionless metrics, (iv) creating a second regression model based on the defined input variables, and (v) testing the first regression model created based on a comparison of at least one predicted value of the regression models using a validation data set. In the case of a result of the testing indicating a match of the predicted values to a defined extent, the following further step is performed: modeling the manufacturing process using the tested first regression model.

This application claims priority under 35 U.S.C. § 119 to patent application no. DE 10 2025 108 857.8, filed on Mar. 10, 2025 in Germany, the disclosure of which is incorporated herein by reference in its entirety.

The disclosure relates to a method for modeling a manufacturing process. The disclosure further relates to a computer program, a device, and a storage medium for this purpose.

### BACKGROUND

Various types of process modeling may be employed as part of manufacturing processes such as joining methods or machining methods. These may be selected based on the availability of physical test parts and data. One goal therein can be to achieve optimum production quality and costs specifically for each task of the manufacturing process.

Particularly at the beginning of manufacturing process development, there are no or only a few physical parts available for testing. For this reason, physical models of the manufacturing process as well as experiential knowledge are often used in early sample phases.

A commonly used concept for early sample phases is a manual, knowledge-based design of the process parameters by a process expert. The nature and scope of changes in parameter values is based on the expertise of the respective process expert as well as part availability.

If no parts are available, a first physical feasibility check of the process can be made using analytical equations known from the literature. However, this estimation does not usually include a detailed consideration of geometric shapes and tolerances.

In order to be able to depict even more complex physical interactions, (multiphysics) simulation models based on the finite element method are also used. This allows the geometry to be mapped more accurately. However, approximate values must also be used here, for example for material modeling or surface properties.

If, in the later course of development, initial experimental results with parameter variations are available, data-based methods can also be used.

By way of simple regression models (e.g., ANOVA), possible relationships between the process variables can be approximated based on test data. These regression models usually only take univariate relationships into account; interactions between multiple parameters and influencing factors are rarely investigated.

Moreover, the current state of the art is also to generate data-based process models using machine learning methods to predict process variables. For example, regression algorithms such as Gaussian models, neural networks, or symbolic regression are used in this context. If there is a change to the process or boundary conditions however, the trained data models or regression models only have reduced prediction accuracy. In this case, the generation of a new training data set is required, which is generally associated with a great deal of time and cost, in order to retrain the model in all dimensions. In this respect, there are approaches such as “transfer learning” in order to at least take the old data into account to a certain extent. If more complex deviations occur, however, it is often necessary to create an entirely new data set and model.

### SUMMARY

The subject matter of the disclosure is a method, a computer program, an apparatus, and a computer-readable storage medium having the features set forth below. Further features and details of the disclosure are also set forth in the description and the drawings. Features and details which are described in connection with the method according to the disclosure naturally also apply in connection with the computer program according to the disclosure, the device according to the disclosure, and the computer-readable storage medium according to the disclosure, and vice versa in each case, so that a reciprocal reference is always possible with regard to the disclosure of the disclosure.

The subject matter of the disclosure is in particular a method for modeling a manufacturing process, for example a laser welding process, in particular that of a production facility such as a laser welding apparatus, comprising:
defining a target variable, input variables, and constant physical variables as part of the manufacturing process, wherein said information can be manually defined and/or automatically retrieved from a database, wherein retrieval from the database can be performed specifically for the manufacturing process,
determining dimensionless metrics, also referred to as pi factors in the context of the present disclosure, based on the defined input variables, the defined target variable, and the defined constant physical variables by way of a dimensional analysis,
creating a first regression model based on the determined dimensionless metrics, wherein the first regression model in particular models a relationship between the determined dimensionless metrics and the defined target variable,
creating a second regression model based on the defined input variables, wherein the second regression model in particular models a relationship between the defined input variables and the defined target variable,
testing the created first regression model based on a comparison of at least one (respective) predicted value, preferably a plurality of predicted values, of the regression models using a validation data set,
   wherein, in the case of a result of the testing indicating a match of the predicted values to a defined extent, the following further step is performed:
modeling the manufacturing process using the tested first regression model.

The first regression model is based on the dimensionless metrics and can thereby be modeled with significantly less computational and preparatory effort, since, for example, less data on the input variables must also be acquired. Thus, significantly reduced computational effort can be enabled by the method according to the disclosure when modeling the manufacturing process. Through testing, it can be ensured that the first regression model is also actually in line with the second regression model, which is based on the actual input values and constant physical variables. Based on a result of this modeling, the manufacturing process can be designed and performed accordingly.

In particular, a regression model is a statistical model that describes the relationship between a dependent variable and one or more independent variables. For example, it serves to analyze and predict data by determining a function that best matches the observed data. For example, linear regression assumes a linear relationship between the variables. More complex regression models, such as non-linear or multiple regressions, may take into account further influencing factors or non-linear relationships.

The first and/or the second regression model may be a machine learning model that is created and trained as part of the creation on the basis of respective training data in order to model the relationship between the determined dimensionless metrics and the defined target variable, or the relationship between the defined input variables and the defined target variable.

Dimensional analysis is in particular a method for determining dimensionless metrics that can simplify and generalize complex physical relationships. In so doing, the variables involved can be broken down into their fundamental dimensions, or base variables (e.g., length, time, mass), and combined into dimensionless metrics by applying the II theorem (Buckingham theorem). These dimensionless metrics enable, for example, a scale-independent analysis of physical processes, can facilitate experimental studies, and can allow model experiments to be transferred to real systems.

It may be advantageous if the disclosure provides that the method further comprises: analyzing an influence or a sensitivity of the input variables on the target variable by way of a sensitivity analysis, wherein the sensitivity analysis is used to investigate in particular how sensitive the target variable is to changes in the input variables, filtering the input variables based on a result of the analysis, for example based on a defined threshold value for the influence, or the sensitivity, or, for example, a defined number of input variables with the greatest influence or sensitivity could be selected, for example three input variables with the greatest influence or sensitivity, wherein the determining of the dimensionless metrics is performed based on the filtered input variables, the defined target variable, and the defined constant physical variables by way of dimensional analysis. Thus, the determination of the dimensionless metrics can be simplified and the required computational effort, especially with a variety of input variables, can be significantly reduced.

In another embodiment, the method may further comprise:
creating a process fitness map using the created second regression model, wherein the process fitness map represents a manufacturing process capability across the determined dimensionless metrics for the (defined or filtered) input variables, the target variable, and the constant physical variables,
determining influential dimensionless metrics for at least one region in the process fitness map, which comprises extreme values, i.e., for example, significantly high or low values, wherein, for example, further data points from regions having extreme values can be omitted or set to zero in order to consider a respective region in isolation and to be able to determine the influential dimensionless metrics for this respective region, wherein the at least one region which includes extremes can be identified, for example, based on an analysis of iso-lines of the process fitness map, wherein the iso-lines in the process fitness map, in particular, limit regions of a particular performance,
creating a local (respective) regression model for the at least one region based on the particular influential dimensionless metrics,
determining an overall regression model for the manufacturing process based on the at least one local regression model created, for which, for example, all present local regression models may be added together,
   wherein the modeling (of the manufacturing process) is performed using the determined overall regression model. By using the local regression models, the manufacturing process can be advantageously differentiated and more precisely modeled.

A further advantage can be achieved within the scope of the disclosure if the method further comprises:
checking the determined influencing dimensionless metrics on the basis of a variation of at least one input variable of the defined input variables on which the determined influencing dimensionless metrics are not based.

Thus, it can be checked whether the determined influencing dimensionless metrics are in fact independent of the further, or at least one further, input variable to ensure that all influencing input variables are actually taken into account. In this way, it can be ensured that the local regression models can precisely model a particular physical phenomenon of the regions having the extreme values.

The disclosure may provide that the method further comprises:
determining a change in the manufacturing process, the defined target variable, at least one of the defined input variables and/or at least one of the defined constant physical variables, for example based on evaluated sensor data of a sensor of the production facility as part of the manufacturing process and/or based on a manual user input,
identifying at least one local regression model affected by the change, for example, by analyzing the dimensionless metrics of the respective local regression models,
modifying the at least one affected local regression model based on the determined change, wherein, for example, the affected local regression model can be recreated or retrained taking into account the determined change,
providing the overall regression model based on the at least one modified local regression model and, in particular, further based on the further unchanged local regression models not affected by the detected change.

Thus, it can advantageously be determined that only a partial modification of the entire regression model is necessary. Thus, the computational effort for adapting to the determined change can advantageously be significantly reduced, as only the affected local regression models need to be modified.

According to an advantageous further development of the disclosure, it can be provided that, if the result of the testing does not indicate that the predicted values match to the defined extent, the following further step is carried out:
defining at least one further input variable and/or at least one further constant physical variable, wherein the at least one further input variable and/or the at least one further constant physical variable can be identified and/or defined manually and/or automatically (e.g., by retrieving from a database).

If the predicted values do not match sufficiently, this may indicate that at least one input variable and/or constant physical variable has not been included in the first regression model. This can be countered by (manually and/or automatically) identifying and appropriately defining further input variables and/or constant physical variables relating to the manufacturing process.

In addition, it is advantageous when the predictive accuracy of the regression models is compared as part of the testing, wherein a threshold of predictive accuracy is provided for the defined extent of the match. In doing so, the validation data set may be used at least in part as a ground truth to determine the predictive accuracy. In other words, predictions using the first regression model and using the second regression model may be performed based on the validation data set. The predicted values are provided in particular as a result of the respective predictions performed. These predicted values may first be compared to the ground truth to determine the predictive accuracy of the respective regression models. Subsequently, these determined predictive accuracies may be compared.

In addition, the method can further comprise:
adjusting the manufacturing process based on a result of modeling.

In this case, the target variable determined in the context of modeling can be applied in a real technical system. As part of a laser welding process, for example, the target variable could be determined in the form of a welding depth and applied in a laser welding apparatus.

Another object of the disclosure is a computer program, in particular a computer program product, comprising instructions which, when the computer program is executed by at least one computer, cause the computer to carry out the method according to the disclosure. The computer program according to the disclosure thus brings about the same advantages as have been described in detail with reference to the method according to the disclosure.

The subject matter of the disclosure is also a device for data processing that is configured to execute the method according to the disclosure. The device can be at least one computer, for example, that executes the computer program according to the disclosure. The computer may have at least one processor for executing the computer program. A non-volatile data memory can be provided as well, in which the computer program can be stored and from which the computer program can be read by the processor for execution.

The disclosure can also relate to a computer-readable storage medium, which comprises the computer program according to the disclosure and/or commands that, when executed by at least one computer, prompt said computer program to carry out the method according to the disclosure. The storage medium is configured, for example, as a data memory such as a hard disk and/or a non-volatile memory and/or a memory card. The storage medium may, for example, be integrated in the computer.

Furthermore, the method according to the disclosure may also be executed as a computer-implemented method. Alternatively or additionally, at least one of the disclosed method steps may be computer-implemented and/or performed automatically.

### BRIEF DESCRIPTION OF THE DRAWINGS

Further advantages, features and details of the disclosure will be apparent from the following description, in which exemplary embodiments of the disclosure are described in detail with reference to the drawings. In this case, the features mentioned in the claims and in the description may in each case be essential to the disclosure individually or in any desired combination. They show:

FIG. 1 a schematic visualization of a method, a production facility having a sensor, a device, a storage medium, and a computer program according to exemplary embodiments of the disclosure.

### DETAILED DESCRIPTION

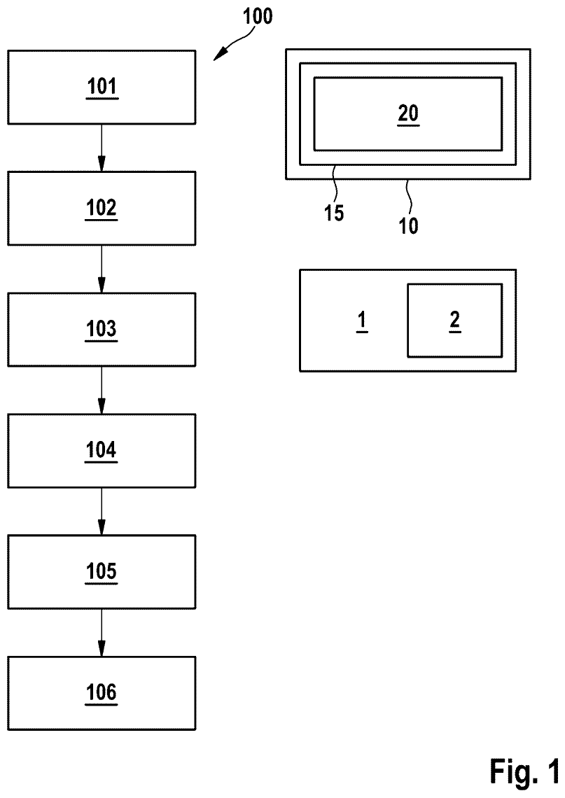

FIG. 1 schematically illustrates a method 100, a production facility 1 with a sensor 2, a device 10, a storage medium 15 and a computer program 20 according to exemplary embodiments of the disclosure.

In particular, FIG. 1 shows an exemplary embodiment of a method 100 for modeling a manufacturing process. In a first step 101, a target variable, input variables, and constant physical variables are defined as part of the manufacturing process. In a second step 102, dimensionless metrics are determined based on the defined input variables, the defined target variable and the defined constant physical variables by way of a dimensional analysis. In a third step 103, a first regression model is created based on the determined dimensionless metrics. In a fourth step 104, a second regression model is created based on the defined input variables. In a fifth step, the created first regression model is tested based on a comparison of at least one (respective) predicted value of the regression models using a validation dataset. In the event of a result of testing 105 indicating a match of the predicted values to a defined extent, a sixth step 106 is performed according to which the manufacturing process is modeled using the tested first regression model.

In accordance with exemplary embodiments of the disclosure, a hybrid process model is provided based on dimensionless metrics, which enables a (semi-) automated design of a manufacturing process.

Contrary to prior-art approaches, modeling the manufacturing process according to the disclosure is based on physical metrics that can be learned based on data. Additionally, a process expert may be able to select a model that is most appropriate for a specific application for modeling. Consequently, in particular, a hybrid model results from data, physical knowledge and expert knowledge, which is not yet known in this form in the prior art. With the help of the hybrid information, it may be possible to increase the robustness of the manufacturing process in the long term, as the knowledge can be combined from multiple domains.

According to exemplary embodiments of the disclosure, a workflow is thus provided for extracting a physically based (regression) model from data. One characteristic of the disclosure is, for example, that, in the workflow, a physically based (regression) model is automatically created from data through the sequence of several work steps. A further characteristic of the disclosure is in particular that different physical phenomena can be described with sub-models or local regression models, respectively. An advantage here is, for example, that when changes are made to an environment or process conditions, the entire model does not have to be retrained, only the individual sub-models or the local regression models. This results in particular, in a further advantage due to the disclosure such that a significantly reduced need for new training data arises in the event of a required re-training of the model, in the case of changed process or boundary conditions, and thus less effort is required.

In a first step of the method according to exemplary embodiments of the disclosure, a target variable and its unit indicated in a base variable as well as input variables (in particular varying variables, e.g., feed rate, power, speed) and their units, preferably indicated in a basic parameter, can be defined.

In physics, in particular, there are seven so-called base quantities (also called base units): time, length, mass, amperage, temperature, amount of substance, and luminous intensity. These variables form in particular the SI system. With the help of these base quantities, further parameters can be set with corresponding units.

In a further step, a definition of known constant physical variables (e.g., gravitational force, material constant), preferably with a unit indicated in a base quantities, may be defined.

Further, based on a software-assisted selection of a manufacturing process to be investigated, relevant constant physical variables may be automatically proposed and selected and/or defined for more precise specification.

For example, in a laser welding process as a manufacturing process, process variables such as speed or power, machine variables such as machine force or spring stiffness, and geometry variables such as component length or volume could be defined as input variables. Constant physical variables may be defined as material constants, such as density or thermal conductivity. A target variable can be defined in the form of a welding depth, for example.

Subsequently, a correlation or sensitivity analysis (English: “Feature Importance Analysis”) may be carried out, i.e., in particular a data-based analysis of the relevance or sensitivity of the input variables to the target variable. Input variables that do not or only have a minor impact on the target variable can be deactivated and not be considered or taken into account further. For example, a regression model may be initially generated with a regression algorithm (e.g., neural network or Gaussian model) for verification. The predictive accuracy of a validation dataset must not degrade in particular through the removal of the input variables classified as “not relevant”.

A dimensional analysis may then be performed, e.g., using the Buckingham theorem (Vaschy-Buckingham π-theorem), to determine dimensionless metrics, in particular pi factors. This may be done based on the target variable, the input variables, and the constant physical variables. This results in particular in one or more decompositions of the dimensionless metrics, in particular pi-factor decompositions, wherein each pi-factor decomposition comprises one or more pi-factors.

In the example of laser welding, a weld depth could be the target variable q₀. Focus diameter, speed, and laser power may be defined as inputs. A thermal conductivity, a density, a specific heat capacity, and a difference between evaporation to room temperature may be defined as material constants, i.e., constant physical variables.

After the dimensional analysis, there is in particular a result in the format

$${π}_{0} = c * f ( {π}_{1} , {π}_{2} , {π}_{3} )$$

To check for completeness of the pi factor decomposition, a regression model can be created with a regression algorithm (e.g., neural network, Gaussian model . . . ) based on the determined pi factors of the individual decompositions.

Here, the following in particular applies:

$${π}_{0} = c * f ( {π}_{1} , {π}_{2} , {π}_{3} )$$

wherein f in particular is an unknown function that may be fitted by symbolic regression or other regression algorithms, and c is a constant factor.

By transforming the equations the following in particular is obtained:

$${q}_{0} = c * ( {q}_{0} / {π}_{0} ) * f ( {π}_{1} , {π}_{2} , {π}_{3} )$$

A regression model Y based on the pi factors may now be created for each pi factor decomposition:

$$Y = c * ( {q}_{0} / {π}_{0} ) * f ( {π}_{1} , {π}_{2} , {π}_{3} )$$

The predictive accuracy (e.g., root mean square error) of this first regression model based on the pi factors, using a validation dataset, must now be particularly similar to the predictive accuracy of a second regression model that was trained or created based on the original input variables.

If the first regression model based on the pi factors generates a poorer prediction than the second regression model based on the input variables, this may be indicative of the manufacturing process not being described completely in physical terms and still lacking one or more input variables or constant physical variables. In this case, additional variables must preferably be selected or defined for the analysis.

In a further step, a process fitness map can be examined for different physical phenomena. To do so, a regression model can be trained based on input variables and the process fitness map can be created. Local optima, i.e., regions with extreme values in the process fitness map are in particular often caused by individual physical phenomena or process properties. By analyzing iso-lines of the process fitness map, these regions with different physical effects can be identified. Subsequently, attempts can be made to determine the pi factors influencing this region. In so doing, data of the regions, or local optima, can be separated and a relevance analysis carried out with the aim of extracting the pi factors (one or more) with which the local optima can be best described. Subsequently, with the pi factors selected in this manner, a local regression model may be formed that is capable of describing the local region.

In order to check the division of the individual physical phenomena and the allocation of the relevant pi factors, or to reduce a selection in several possible pi factor decompositions, experimental parameters can be specifically derived.

For example, a first physical phenomenon could be described with Y₁=f(π₁, π₂)

$${π}_{2} = f ( λ / ( P * dT )$$

wherein λ and dT, in particular, are material constants and P is an input variable, and

$${π}_{1} = f ( dt * v / cp )$$

wherein cp and dt are material constants and v an input variable.

It could be determined, for example, that the input variable focus diameter df does not occur in Y₁. Thus, targeted design of experiments can be performed with a constant P and v and a variation of df to check this correlation, whereby other relevant pi factors may also be identified, if necessary.

An entire regression model can then be formed based on the sub-models, or local regression models, respectively. The entire regression model is preferably then formed from a sum of the sub-models, or local regression models, in order to be able to map a complete region.

$$Y + {Y}_{1} + {Y}_{2} + … {Y}_{n}$$

Further, re-training may be provided upon a change in the boundary or process conditions. Often, when changing environmental, material, or process conditions, only the effect on individual physical phenomena may change. Therefore, in this case, it is in particular sufficient to retrain only the associated sub-model, or local regression model, e.g. Y₁=f(π₁). For this purpose, it is then particularly sufficient to vary the input variables, which are varied in the pi factors of the sub-model with the deviations in new experiments, and to retrain the specific regression model with these data points, e.g. π₁=f(λ/(P*dT). Since λ and dT are material constants, only a variation of P in particular is required.

The foregoing explanation of the exemplary embodiments describes the present disclosure exclusively in the context of examples. Of course, individual features of the embodiments can be freely combined with one another, if technically feasible, without leaving the scope of the present disclosure.

What is claimed is:

1. A method of modeling a manufacturing process, comprising:
defining a target variable, input variables, and constant physical variables within the manufacturing process;
determining dimensionless metrics based on the defined input variables, the defined target variable, and the defined constant physical variables by way of a dimensional analysis;
creating a first regression model based on the determined dimensionless metrics;
creating a second regression model based on the defined input variables; and
testing the first regression model created based on a comparison of at least one predicted value of the regression models using a validation data set,
wherein, in the case of a result of the testing indicating a match of the predicted values to a defined extent, the following is performed: modeling the manufacturing process using the tested first regression model.

2. The method according to claim 1, further comprising:
analyzing an influence of the input variables on the target variable by way of a sensitivity analysis; and
filtering the input variables based on a result of the analyzing,
wherein the determining of the dimensionless metrics is performed based on the filtered input variables, the defined target variable, and the defined constant physical variables by way of the dimensional analysis.

3. The method according to claim 1, further comprising:
creating a process fitness map using the created second regression model, wherein the process fitness map represents a manufacturing process capability across the respective determined dimensionless metrics for the input variables, the target variable, and the constant physical variables;
determining influential dimensionless metrics for at least one region in the process fitness map that includes extreme values;
creating a local regression model for the at least one region based on the respectively determined influential dimensionless metrics; and
determining an overall regression model for the manufacturing process based on the at least one generated local regression model,
wherein the modeling is performed using the determined overall regression model.

4. The method according to claim 3, further comprising:
checking the determined influencing dimensionless metrics based on a variation of at least one input variable of the defined input variables on which the determined influencing dimensionless metrics are not based.

5. The method according to claim 3, further comprising:
determining a change in the manufacturing process, the defined target variable, at least one of the defined input variables and/or at least one of the defined constant physical variables;
identifying at least one local regression model that is affected by the change;
modifying the at least one affected local regression model based on the determined change; and
providing the overall regression model based on the at least one modified local regression model.

6. The method according to claim 1, wherein:
in the event of a result of the testing that does not indicate a match of the predicted values to the defined extent, the following is performed: defining at least one further input variable and/or at least one further constant physical variable.

7. The method according to claim 1, wherein:
as part of the testing, a predictive accuracy of the regression models is compared, and
a threshold of the predictive accuracy is provided for the defined extent of the match.

8. The method according to claim 1, further comprising:
adjusting the manufacturing process based on a result of modeling.

9. A computer program, comprising commands which, when the computer program is executed by at least one computer, cause the latter to execute the method according to claim 1.

10. An apparatus for data processing, configured so as to carry out the method according to claim 1.

11. A computer-readable storage medium, comprising instructions which, when executed by at least one computer, cause said computer to carry out the method according to claim 1.
